(19) United States
(12) Patent Application Publication
(10) Pub. No.: US 2010/0015762 A1
(43) Pub. Date: Jan. 21, 2010

(54) Solder Interconnect

(76) Inventors: Mohammad Khan, Saratoga, CA (US); Ranjit Gannamani, San Jose, CA (US); Charlie Zhai, San Jose, CA (US); Shirsho Sengupta, Santa Clara, CA (US); Robert Newman, Santa Clara, CA (US)

Correspondence Address: TIMOTHY M HONEYCUTT ATTORNEY AT LAW, P O BOX 1577, CYPRESS, TX, 77410, US

(21) Appl. No.: 12/173,105

(22) Filed: Jul. 15, 2008

(51) Int. Cl. H01L 21/56

(52) U.S. Cl. 438/124; 257/E21.503

(57) ABSTRACT

Various solder interconnect methods and apparatus are disclosed. In aspect, a method of manufacturing is provided that includes coupling a semiconductor chip to a circuit board with plural solder joints whereby an interstitial space is left between the semiconductor chip and the circuit board. The semiconductor chip and the circuit board are heated at a first temperature lower than a melting point of constituents of the plural solder joints to liberate contaminants from the interstitial space. The semiconductor chip and the circuit board are heated again at a second temperature higher than a melting point of at least one the constituents but not all of the constituents of the plural solder joints to shrink grain sizes of the at least one constituent. An underfill is placed in the interstitial space.

### BACKGROUND OF THE INVENTION

1. Field of the Invention

This invention relates generally to semiconductor processing, and more particularly to methods and apparatus for connecting a semiconductor chip to a circuit board.

2. Description of the Related Art

Conventional semiconductor chips are often mounted on and electrically connected to a printed circuit board of one sort or another. Examples include package substrates or chip carriers, motherboards, application specific cards and others. Surface mounting is one type of mounting/interconnect technique and there are several variants of this basic technique. One very widely-used technique is flip-chip controlled collapse chip connection (C4) in which electrical connections between the chip and the package substrate, board etc. are established by creating an array of C4 solder joints. In one type of conventional lead-based process, an array of high lead content tin-lead (97Pb 3Sn) solder bumps are formed on conducting I/O bump pads of the chip. A corresponding array of eutectic tin-lead (63Sn 37Pb) solder structures are formed on conducting I/O pads of the package substrate. The chip is placed bump side down on the package substrate so that the two arrays of solder structures line up and reflow is performed above the melting point of the eutectic package bumps, but below the melting point of the chip bumps. The eutectic bumps melt and wet to the chip bumps. A subsequent cool down yields the finished solder joints.

In a typical conventional semiconductor chip package, the solder joints connect materials of highly disparate thermal expansion properties. For example, a silicon chip typically has a coefficient of thermal expansion of about 3.0 10⁻⁶ K⁻¹, while a typical organic package substrate has a CTE of about 15.0 to 20.0 10⁻⁶ K⁻¹. The solder joints themselves will typically have CTE's that are different still. Consequently, fatigue stresses due to thermal expansion mismatch is of great concern.

To help alleviate some of the CTE mismatch issues, an underfill material is often placed in the interstitial space between the chip and the board/substrate to which it is attached. A typical underfill is composed of an epoxy that, upon hardening, has a CTE that is as low as possible and preferably very close to the CTE of the solder joints. In many conventional processes, the underfill is dispensed at the edges of the chip and capillary action relied upon to fill the chip-to-substrate interstitial space. Any voids remaining in the underfill after solidification can adversely impact product reliability. Consequently, an extensive pre-bake is performed in the chip-substrate combination following the C4 reflow but before underfill application. A typical pre-bake may involve two or more hours of heating at temperatures of 170° C. or so. The goal is to liberate any water or other contaminants that might create voids, or inhibit underfill adhesion or capillary flow. The pre-bake, though necessary, introduces another issue: grain coarsening.

Conventional flip-chip solder joints are generally non-homogeneous structures. From the bottom up, a typical solder joint consists of (1) the base metal of the package substrate bump pad, (2) one or more solid solutions of a solder constituent—typically tin—with the package substrate bump pad base metal, (3) the solder grain structure, consisting of at least two phases containing different proportions of the solder constituents as well as any deliberate or inadvertent contaminations, (4) one or more solid solutions of a solder constituent—typically tin—with the chip bump pad base metal, and (5) the base metal of the chip bump pad. The grain structure of solder is inherently unstable, particularly for the portion of the joint associated with the eutectic solder composition. The tin grains will grow in size over time as the grain structure reduces the internal energy of a fine-grained structure. This grain growth process is enhanced by elevated temperatures, such as those associated with the underfill pre-bake, as well as strain energy input during cyclic loading. Larger grains translate into reduced fatigue life for the joints.

The present invention is directed to overcoming or reducing the effects of one or more of the foregoing disadvantages.

### SUMMARY OF THE INVENTION

In accordance with one aspect of the present invention, a method of manufacturing is provided that includes coupling a semiconductor chip to a circuit board with plural solder joints whereby an interstitial space is left between the semiconductor chip and the circuit board. The semiconductor chip and the circuit board are heated at a first temperature lower than a melting point of constituents of the plural solder joints to liberate contaminants from the interstitial space. The semiconductor chip and the circuit board are heated again at a second temperature higher than a melting point of at least one the constituents but not all of the constituents of the plural solder joints to shrink grain sizes of the at least one constituent. An underfill is placed in the interstitial space.

In accordance with another aspect of the present invention, a method of manufacturing is provided that includes coupling a first plurality of tin-lead solder bumps to a side of a semiconductor chip and coupling a second plurality of tin-lead solder bumps to a side of semiconductor chip package substrate. The first and second pluralities of tin-lead solder bumps are brought into proximity and a reflow is performed to melt and wet the second plurality of tin-lead solder bumps to the first plurality of tin-lead solder bumps whereby an interstitial space is left between the semiconductor chip and the semiconductor chip package substrate. The semiconductor chip and the semiconductor chip package substrate are heated at a first temperature lower than a melting point of the first and second pluralities of tin-lead solder bumps to liberate contaminants from the interstitial space. The semiconductor chip and the semiconductor chip package substrate are heated again at a second temperature higher than a melting point of the second plurality of tin-lead solder bumps but not the first plurality of tin-lead solder bumps to shrink grain sizes of tin in the second plurality of tin-lead solder bumps. An underfill is placed in the interstitial space.

In accordance with another aspect of the present invention, a method of manufacturing is provided that includes coupling a semiconductor chip to a circuit board with plural solder joints. Each of the plural solder joints has a conductive pillar coupled to the semiconductor chip and a solder structure coupled to the circuit board. The conductive pillar and the solder structure are metallurgically bonded. An interstitial space is left between the semiconductor chip and the circuit board. The semiconductor chip and the circuit board are heated at a first temperature lower than a melting point of constituents of the solder structures solder joints to liberate contaminants from the interstitial space. The semiconductor chip and the circuit board are heated again at a second temperature higher than a melting point of plural solder structures joints to shrink grain sizes of the at least one constituent of the plural solder structures. An underfill is placed in the interstitial space.

### BRIEF DESCRIPTION OF THE DRAWINGS

The foregoing and other advantages of the invention will become apparent upon reading the following detailed description and upon reference to the drawings in which:

FIG. 1 is a sectional view of an exemplary embodiment of a semiconductor chip coupled to a circuit board;

FIG. 2 is a magnified view of a portion of FIG. 1;

FIG. 3 is a magnified sectional like FIG. 2 but depicting various exemplary process steps to establish a solder joint;

FIG. 4 is a sectional view like FIG. 3 depicting further processing to establish the solder joint;

FIG. 5 is a flow chart depict exemplary process steps to establish a solder joint;

FIG. 6 is a sectional view like FIG. 4 but of a conventional solder joint fabrication process; and

FIG. 7 is a sectional view like FIG. 4 but of an alternate exemplary embodiment of a semiconductor chip coupled to a circuit board.

### DETAILED DESCRIPTION OF SPECIFIC EMBODIMENTS

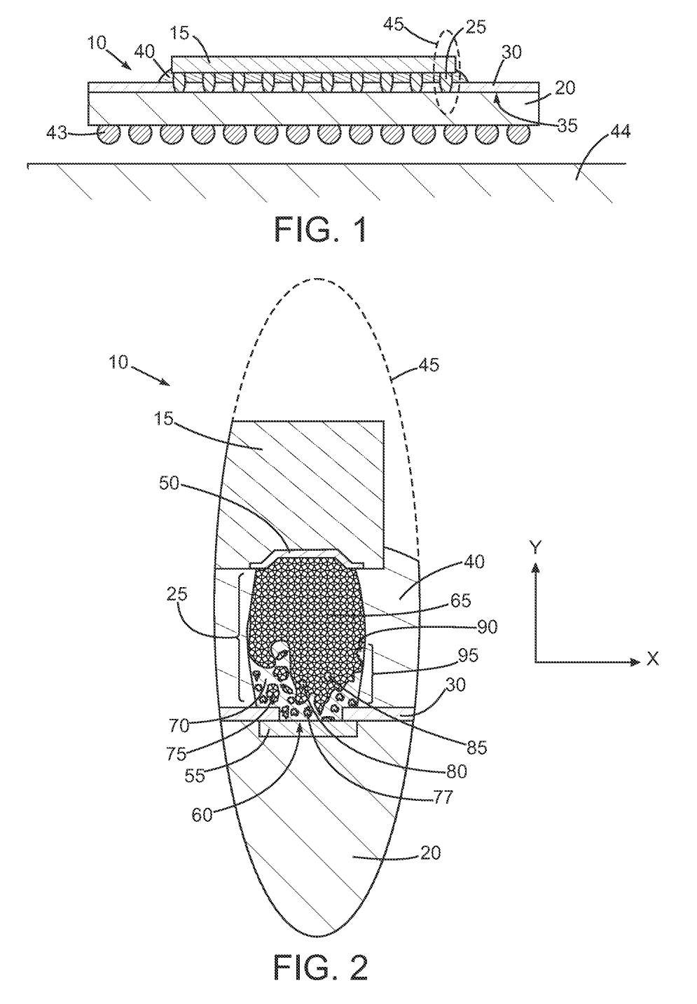

In the drawings described below, reference numerals are generally repeated where identical elements appear in more than one figure. Turning now to the drawings, and in particular to FIG. 1, therein is shown a sectional view of an exemplary conventional semiconductor chip package 10 that includes a semiconductor chip 15 mounted in flip-chip fashion on a package substrate 20. Electrical interconnections between the chip 15 and the package substrate 20 are provided by way of a plurality of solder joints 25. A solder mask 30 is provided on the upper surface 35 of the substrate 20 in order to facilitate the fabrication of the solder joints 25. An underfill material layer 40 is positioned between the chip 15 and the solder mask 30. The underfill material layer 40 is designed to alleviate some of the stresses on the solder joints 25 as a result of substantial differences in the CTE of the chip 15 and the substrate 20. The package 10 may be lidless as depicted or optionally provided with a lid or heat spreader.

The chip 15 may be configured as virtually any type of device, such as a microprocessor, a graphics processor, a combined microprocessor/graphics processor, a memory device, an application specific integrated circuit or the like. Such devices may be multiple core and multiple dice. The chip 15 is depicted as being mounted in a flip-chip fashion, however, multiple dice could be stacked or mounted to the substrate 20 in a stack or unstacked configuration as desired.

The substrate 20 may interconnect electrically with some other device 44, such as a circuit board, a computing device or other electronic device, by way of variety of interconnect schemes. In this illustrative embodiment, plural interconnect structures in the form of a ball grid array consisting of a plurality of solder balls 43 are coupled to the substrate 20 in order to interface the package 10 with the other device 44. However, other interconnect schemes, such as a pin grid array, a land grid array or others may be used. Structurally speaking, the substrate 20 may be composed of ceramics or organic materials. If an organic design is selected, the substrate 20 may consist of a core/build-up configuration. In this regard, the substrate 20 may consist of a central core upon which one or more build-up layers are formed and below which an additional one or more build-up layers are formed. The core itself may consist of a stack of one or more layers. One example of such an arrangement may be termed a so called “2-4-2” arrangement where a four-layer core laminated between two sets of two build-up layers. The number of layers in the substrate 20 can vary from four to sixteen or more, although less than four may be used. So-called “coreless” designs may be used as well. The layers of the substrate 20 consist of an insulating material, such as various well-known epoxies, interspersed with metal interconnects.

Additional details of the solder joint 25 may be understood by referring now to FIG. 2, which is a magnified view of the portion of FIG. 1 circumscribed by the dashed oval 45. The description of the solder joint 25 is illustrative of the other solder joints between the chip 15 and the substrate 20. The solder joint 25 is metallurgically bonded to a bump pad or sometimes called an under bump metallization structure 50 in the semiconductor chip 15. The bump pad 50 is electrically connected to other interconnect structures within the chip 15, such as conductor lines and vias that are not visible in FIG. 2. The lower end of the solder joint 25 is metallurgically connected to a bump pad 55 in the package substrate 20. Like the bump pad 50, albeit in a different context, the bump pad 55 is electrically connected to other circuit structures and conductors in the substrate 20 that are not visible in FIG. 2. The bump pad 50 may be fabricated from copper, silver, gold, platinum, palladium, combinations of these or the like. The bump pad 55 may be fabricated from the same types of materials. The solder mask 30 may be fabricated from a variety of suitable materials for solder mask fabrication, such as, for example, PSR-4000 AUS703 manufactured by Taiyo Ink Mfg. Co., Ltd. or SR7000 manufactured by Hitachi Chemical Co., Ltd. The solder mask 30 is patterned with an opening 60 by well-known lithographic techniques. The opening 60 leads to the bump pad 55. The underfill material 40 alleviates some of the sheering stresses and strains that are imparted on the solder joint 25 generally along the X-axis as well as some restraint on axial stresses and strains say along the Y-axis.

As described in conjunction with subsequent figures, the solder joint 25 is not a homogeneous structure. Rather, the solder joint 25 is a combination of two solder structures, one that is previously attached to the chip 15 and the other which is previously attached to the substrate 20. The two structures are brought together and a reflow is performed. The solder joint 25 consists of a large region of relatively small grain lead 65 that is depicted with a weave pattern in the figure, and a smaller and irregularly shaped region of majority tin 70 that is cross-hatched. There are smaller grains of lead also depicted with a weave pattern. A couple of the lead grains are numbered 75 and 77. The lead grains 75 and 77 and others are interspersed within the tin grains 70. Conversely, a few tin grains 80, 85 and 90, that are too small in the FIG. 2 to be practically cross-hatched, are interspersed within the lead 65.

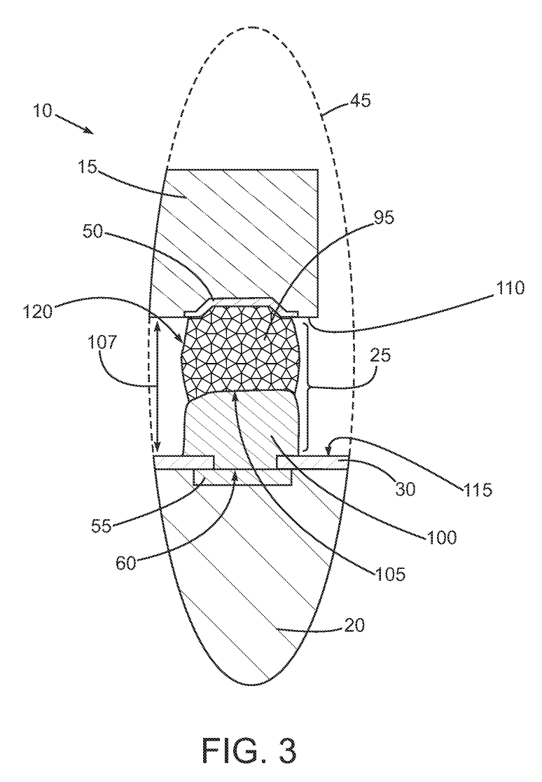

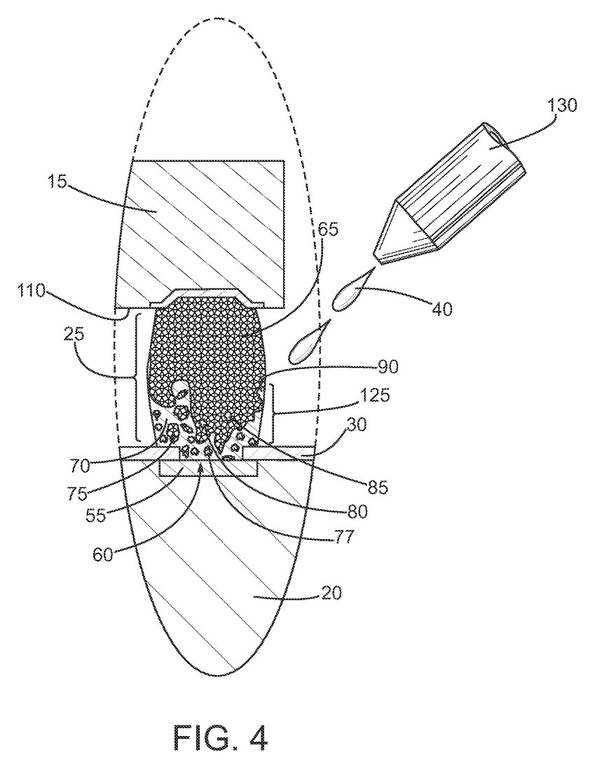

Process steps that lead to the formation of the solder joint 25 are described in conjunction with FIGS. 3 and 4, which are successive sectional views of the solder joint 25 during various stages of processing. Again, the focus is on the solder joint 25 and thus the dashed oval portion 45. FIG. 3 depicts the solder joint 25 just after a solder bump 95 of the chip 15 is brought into contact with the solder bump 100 of the package 20. Prior to this physical contact, the solder bump 95 is attached to the under bump metallization 50 and a reflow process is performed to establish the requisite metallurgical connection between the pad 50 and the bump 95. The bump 95 is typically composed of a high content lead-tin solder of say about 97% lead and about 3% tin. Prior to making the physical connection between the solder bumps 95 and 100, the solder bump 100 is formed on the bump pad 60 by depositing a solder paste of lead and tin, typically at the eutectic composition of about 63% tin and 37% lead. With these respective compositions, that is, the high lead composition for the bump 95 and the low lead composition for the bump 100, the bump 100 will have a much lower melting point then the bump 95. Prior to the physical joining between the bumps 95 and 100, the bump 100 will typically undergo a coining process to flatten an upper surface 105 thereof. After the respective bumps 95 and 100 are formed, the chip 15 is brought into close proximity with the package substrate 20 such that the bumps 95 and 100 physically contact. At this stage, a reflow process is formed above the melting point of the solder bump 100 but below the melting point of the solder bump 95. During this reflow process, the solder of the bump 100 will liquify and wet to the bump 95 as well as the portion of the underlying bump 55 that is exposed by the opening 60 in the solder mask 30. The joint 25 is then allowed to cool and solidify into a somewhat continuous metallurgical structure. The joint 25 elevates the chip 15 above the substrate 20 to leave an interstitial space 107 between a lower surface 110 of the chip 15 and an upper surface 115 of the solder mask 30 and thus the substrate 20.

The reflow to establish the metallurgical bonding between the bumps 95 and 100 is typically performed by heating the package 10, for example in a furnace, using a thermal cycle that produces the following temperatures in the joint 25: the temperature is ramped up to 140 to 150° C. in about 4 to 5 minutes, then held at that temperature for a minute or two, then ramped up to a peak of about 220 to 240° C. for about 1 to 2 minutes, and then ramped down to room temperature in about 5 to 6 minutes. These times and temperatures may be varied. The reflow is of sufficient duration to activate flux present on the interfacing surfaces of the bumps 95 and 100 that must be activated and out gassed sufficiently in order for the metallurgical bond between the bumps 95 and 100 to fully form.

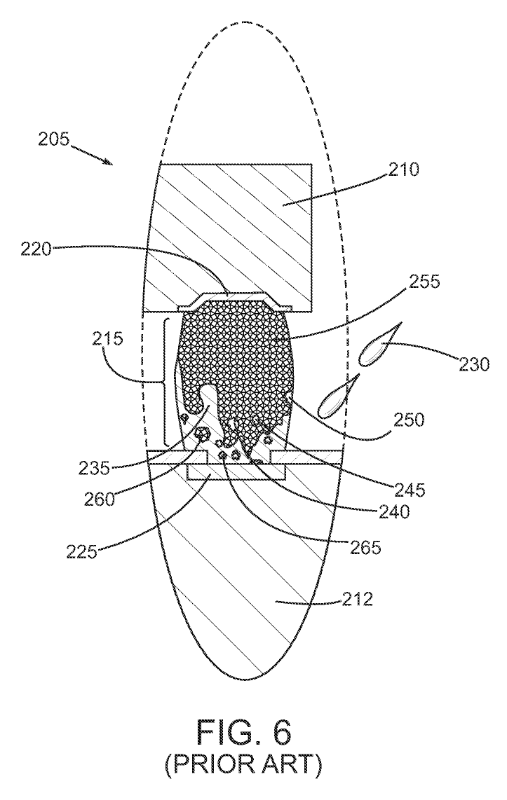

After the reflow to establish the solder joint 25, a prebake process is performed on the package 10 as a precursor to application of the underfill material layer 40 depicted in FIGS. 1 and 2. The purpose of the prebake is to eliminate any contaminants, such as water, left over flux, or other contaminants from the interstitial space 107 that might restrict the ability of the underfill material layer (see FIGS. 1 and 2) to adhere to the lower surface 110 of the chip 15 and the upper surface 115 of the solder mask 30 as well as the exterior surface 120 of the solder joint 25. The prebake is typically performed at about 165° C. for about three hours. The temperature is not high enough to melt any portion of the joint 25. However, the temperature is high enough and maintained for a long enough duration to cause grain coarsening as will be described below in conjunction with FIG. 6.

Following the underfill prebake, the solder joint 25 is subjected to a second brief reflow process. Attention is turned now to FIG. 4, which shows the package 10 and joint 25 following the second reflow. The purpose of the second reflow is to briefly melt at least one constituent, in this case tin, in the lower half 125 of the solder joint 25, that is, the eutectic composition solder bump. It may be somewhat artificial to use terms such as “lower half” and such to describe the melting process since the joint 25 at this stage is nowhere near homogenous in structure and composition. Suffice it to say that the likelihood of melting in the region 125 of the joint 25 is much more likely than nearer the lower surface 110 of the chip 15. During the brief melting, the grain sizes of tin grains 70, 80, 85 and 90 are decreased and the dispersal of lead grains 75 and 77 within the tin 70 is increased. The fatigue strength of the joint 25 is increased. The duration and temperature for the second reflow may be about 5 to 10 minutes at about 175 to 230° C.. Because there is no need to activate flux or obtain full wetting with the high lead content bump of the chip 15, the duration for the second reflow may be kept relatively short. Following the second reflow, the underfill material 40 may be deposited between the chip 15 and the package substrate 20 by way of an applicator 130 using a well-known capillary injection process. The underfill material 40 may then be subject to a thermal curing process of about 160° C. for about 30 to 90 minutes. In another option, the solder bump 95 shown in FIG. 3 that becomes part of the joint 25 may be composed of solder having lower than 97% lead content, and thus have a lower melting point.

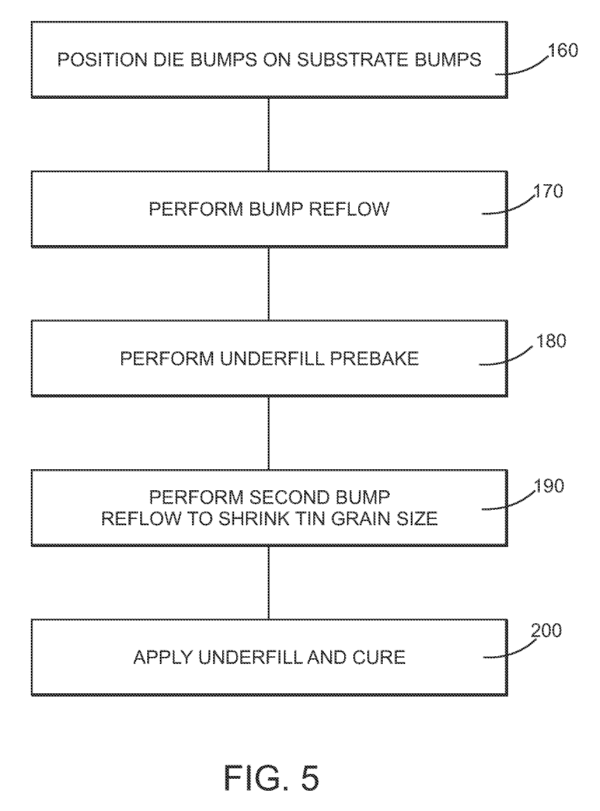

The exemplary method just described may be briefly summarized in conjunction with the flow chart depicted in FIG. 5. At step 160, the die bumps of a given die are positioned on corresponding substrate bumps on a package substrate. At the next step 170, a bump reflow process is performed to establish initial metallurgical bonding between the die and substrate bumps. Next, at step 180, an underfill prebake process is performed. Next, at step 190, a second bump reflow is performed to shrink the grain size of the tin grains within the solder joint. Next, and at step 200, an underfill material layer may be deposited and subjected to a curing process.

It may be useful at this point to consider a conventional die bump attach and underfill process. Attention is turned to FIG. 6, which is a sectional view like FIG. 4, but of a conventional package 205 that includes a semiconductor chip 210 flip-chip mounted to a package substrate 212. A solder joint 215 consisting of a C4 combination of a high-lead die bump and a eutectic tin-lead bump is established between a die pad 220 and a package pad 225 using the techniques generally describe elsewhere herein. However, the package 205 is subjected to a prebake and subsequent application of underfill 230 without the benefit of the grain shrinking second reflow. The aftermath of the prebake is shown. Note the large tin grains 235, 240, 245 and 250 generally, even up into the bulk majority lead region 255, and the relatively small dispersal of lead grains, such as the grains 260 and 265. This relatively coarse grain structure for the tin 235, 240, 245 and 250 is an unwanted by-product of the prebake process that is performed on the package 205 prior to the application of the underfill material layer 230. The high temperature heating process extended over a period of three or so hours causes the coarsening of the tin grains 235, 240, 245 and 250. It turns out that the fatigue strength of the joint 215 is inversely proportional to the tin grain size. Thus, larger tin grain sizes produce a correspondingly smaller joint strength at least as it relates to fatigue. Another mechanism that may contribute to the coarsening of the tin grains 235, 240, 245 and 250 is the potential migration of gold from the package pad 225 into the solder joint 215 during the extended prebake. It is believed that the presence of migratory gold also leads to a coarsening of the grains of tin.

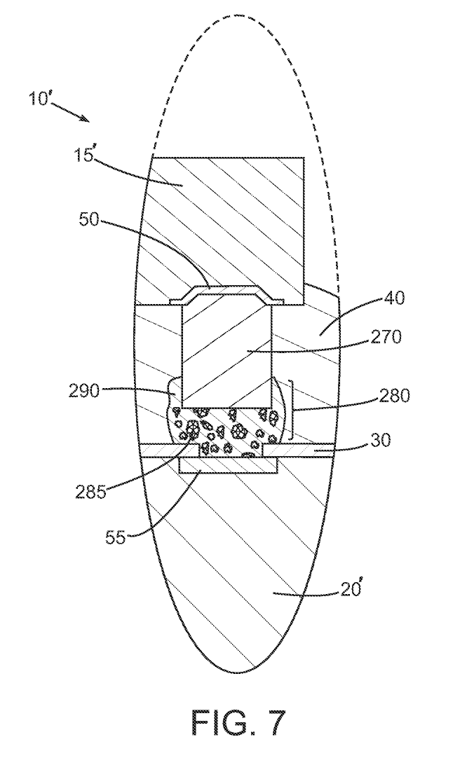

An alternate exemplary embodiment of a semiconductor chip package 10 that uses conductive pillars in conjunction with solder structures to establish an electrical interconnects between a semiconductor chip 15′ and a package substrate 20′ may be understood by referring now to FIG. 7, which is a sectional view of similar scope as FIG. 4. The substrate 20′ may be provided with a solder mask 30 and bump pad 55 and the chip 15′ may be provided with a bump pad 50 that all may be configured as generally described elsewhere herein. Similarly, an underfill material layer 40 may be used as described elsewhere herein. The principal difference in this illustrative embodiment is that, in lieu of a high lead content solder bump on the chip 15′, a conductive pillar 270 is used. The conductive pillar 270 may be composed of a variety of materials such as copper, gold, platinum, silver, combinations of these or like. The conductive pillar 270 is typically plated to the bump pad 50. The package substrate 20′ may be provided with a solder bump 280 that is metallurgically bonded to the bump pad 55. The bump 280 may have the same composition as the eutectic tin-lead bump 100 described in conjunction with FIG. 3. The composition of the solder bump 280 may such that there will be a plurality of lead grains 285, shown with weave pattern, interspersed with a plurality of tin grains shown collectively as the cross-hatched portion 290. The same post underfill prebake second reflow process as described elsewhere herein may be used in conjunction with the solder structure 280 in order to improve the joint strength by shrinking the sizes of the tin grains 290. The second reflow should be performed at a temperature below the melting point of the solder structure 275 so that the conductive pillar 270 does not lose proper alignment.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

1. A method of manufacturing, comprising:
coupling a semiconductor chip to a circuit board with plural solder joints whereby an interstitial space is left between the semiconductor chip and the circuit board, each of the plural solder joints including a first portion coupled to the semiconductor chip and a second portion coupled to the circuit board, the second portion including a majority concentration of tin having plural grains with plural sizes;
heating the semiconductor chip and the circuit board at a first temperature lower than a melting point of constituents of the plural solder joints to liberate contaminants from the interstitial space;
heating the semiconductor chip and the circuit board at a second temperature higher than a melting point of at least the second portions of the plural solder joints to shrink the grain sizes of at least some of the tin grains; and
placing an underfill in the interstitial space.

2. The method of claim 1, wherein the coupling the semiconductor chip to a circuit board with plural solder joints comprises coupling the first plurality of solder joint portions on the chip and the second plurality of solder joint portions on the circuit board, bringing the first and second plurality of solder joint portions into close proximity and reflowing the second plurality of solder joint portions to wet to the first plurality of solder joint portions.

3. The method of claim 2, wherein the first plurality of solder joint portions comprise tin-lead solder with a majority lead composition and the second plurality of solder joint portions comprise tin-lead solder with a eutectic composition.

4. The method of claim 1, wherein the semiconductor chip comprises a processor.

5. The method of claim 4, wherein the circuit board comprises a package substrate.

6. (canceled)

7. The method of claim 1, comprising coupling plural interconnect structures to the circuit board to enable the circuit board to electrically interface with another device.

8. The method of claim 7, wherein the plural interconnect structures comprise solder balls.

9. The method of claim 1, comprising electrically connecting the circuit board to another device.

10. A method of manufacturing, comprising:
coupling a first plurality of tin-lead solder bumps to a side of a semiconductor chip;
coupling a second plurality of tin-lead solder bumps to a side of a semiconductor chip package substrate;
bringing the first and second pluralities of tin-lead solder bumps into proximity and performing a reflow to melt and wet the second plurality of tin-lead solder bumps to the first plurality of tin-lead solder bumps whereby an interstitial space is left between the semiconductor chip and the semiconductor chip package substrate;
heating the semiconductor chip and the semiconductor chip package substrate at a first temperature lower than a melting point of the first and second pluralities of tin-lead solder bumps to liberate contaminants from the interstitial space;
heating the semiconductor chip and the semiconductor chip package substrate at a second temperature higher than a melting point of the second plurality of tin-lead solder bumps but not the first plurality of tin-lead solder bumps to shrink grain sizes of tin in the second plurality of tin-lead solder bumps; and
placing an underfill in the interstitial space.

11. The method of claim 10, wherein the second plurality of tin-lead solder bumps comprise tin-lead solder with a eutectic composition.

12. The method of claim 10, wherein the semiconductor chip comprises a processor.

13. The method of claim 10, comprising coupling plural interconnect structures to the circuit semiconductor chip package substrate to enable the semiconductor chip package substrate to electrically interface with another device.

14. The method of claim 13, wherein the plural interconnect structures comprise solder balls.

15. The method of claim 10, comprising electrically connecting the semiconductor chip package substrate to another device.

16. A method of manufacturing, comprising:
coupling a semiconductor chip to a circuit board with plural solder joints, each of the plural solder joints having a conductive pillar coupled to the semiconductor chip and a solder structure coupled to the circuit board, the conductive pillar and the solder structure being metallurgically bonded, whereby an interstitial space is left between the semiconductor chip and the circuit board;
heating the semiconductor chip and the circuit board at a first temperature lower than a melting point of constituents of the solder structures to liberate contaminants from the interstitial space;
heating the semiconductor chip and the circuit board at a second temperature higher than a melting point of the plural solder structures to shrink grain sizes of the at least one constituent of the plural solder structures; and
placing an underfill in the interstitial space.

17. The method of claim 16, wherein the conductive pillars comprises copper pillars.

18. The method of claim 16, wherein the plurality of solder structures comprise tin-lead solder with a eutectic composition.

19. The method of claim 16, wherein the circuit board comprises a semiconductor chip package substrate.

20. The method of claim 16, comprising electrically connecting the circuit board to another device.
